(19) United States
(12) Patent Application Publication
(10) Pub. No.: US 2026/0105217 A1
(43) Pub. Date: Apr. 16, 2026

(54) SCORE MODELLING FOR SIMULATION-BASED INFERENCE

(71) Applicant: Deepmind Technologies Limited, London (GB)

(72) Inventors: Andriy Mnih, London (GB); Tomas Geffner, London (GB)

(21) Appl. No.: 19/115,358

(22) PCT Filed: Sep. 26, 2023
(86) PCT No.: PCT/EP2023/076529

§ 371 Date: Mar. 26, 2025

Related U.S. Application Data
(60) Provisional application No. 63/410,158, filed on Sep. 26, 2022.
(60) Provisional application No. 63/441,403, filed on Jan. 26, 2023.

(51) Int. Cl. G06F 30/27

(52) U.S. Cl. CPC G06F 30/27

(57) ABSTRACT

Methods, systems, and apparatus, including computer programs encoded on a computer storage medium, for using simulation-based inference to inferring a set of parameters such as measurements, from observations, e.g. real world observations. The method uses a score generation neural network to determine scores for individual observations or for groups of observations that are combined and used to iteratively adjust values of the parameters.

### CROSS-REFERENCE TO RELATED APPLICATION

This application claims priority to U.S. Provisional Applications No. 63/410,158, filed on Sep. 26, 2022, and No. 63/441,403, filed on Jan. 26, 2023. The disclosure of the prior applications is considered part of and is incorporated by reference in the disclosure of this application.

### BACKGROUND

This specification relates to simulation-based inference using neural networks.

Neural networks are machine learning models that employ one or more layers of nonlinear units to predict an output for a received input. Some neural networks include one or more hidden layers in addition to an output layer. The output of each hidden layer is used as input to the next layer in the network, i.e., the next hidden layer or the output layer. Each layer of the network generates an output from a received input in accordance with current values of a respective set of parameters.

### SUMMARY

This specification describes a system, implemented as computer programs on one or more computers in one or more locations, for simulation-based inference. For example, given a black box simulator of some physical process, that uses a set of input parameters to generate a simulation output, the described techniques can invert the process to infer a set of input parameters, i.e. measurements, from real world observations. The described techniques have applications across a wide range of scientific, medical and engineering domains.

In one aspect there is described a method, and a corresponding system, implemented by one or more computers in one or more locations, for determining a set of simulator parameters for a simulator, e.g. representing one or more measurements of a real-world physical system. The simulator is configured to generate a simulated observation, e.g. of the real-world physical system, in accordance with the set of simulator parameters.

The method comprises receiving a set of one or more observations, e.g. of the real-world physical system, and sampling initial values for the set of simulator parameters from a reference distribution, e.g. a Gaussian distribution. The method updates current values for the set of simulator parameters at each of a succession of time (update) steps.

In implementations the updating involves determining, for each of the simulator parameters, a respective parameter adjustment value for the current value of the simulator parameter and for the set of observations. An updated value for each of the simulator parameters can then be determined using the respective parameter adjustment value for the current value of the simulator parameter.

In implementations determining the respective parameter adjustment value for each of the simulator parameters uses a score generation neural network (trained using the simulator) to process, for each observation, i) an embedding of the current value of the simulator parameter, ii) an embedding of the observation, in particular an embedding of one or more of the observations, and iii) an embedding of an index (e.g., a time or count) of the current time step, to generate a score for the observation. The scores for the observations may then be summed to determine the respective parameter adjustment value for the current value of the simulator parameter.

In some implementations the score generation neural network processes just one observation at a time. In some implementations the score generation neural network processes groups of two or more observations at a time. That is the score generation neural network can process one or more observations (and can generate the score for one or more observations).

In implementations the score generation neural network processes an embedding of the current value of each of the simulator parameters and generates an output that comprises the score for each of (all of) the simulator parameters. In implementations the simulator parameters are processed in parallel by the score generation neural network and the scores and respective parameter adjustment values are also determined in parallel.

The subject matter described in this specification can be implemented in particular embodiments so as to realize one or more of the following advantages.

In general simulation-based inference allows characteristics of a real-world physical system to be inferred in cases where it is possible simulate observations of the system based on those characteristics, but difficult to solve the inverse problem. For example, one benchmark is the Weinberg simulator (Louppe et al., arXiv: 1707.07113), which simulates electron-positron collisions in which the angular distribution of particles can be used to infer, i.e. measure, the Fermi constant.

One drawback with simulation-based inference is that many simulator calls can be needed for accurate approximations, which may be problematic with expensive simulators. Neural Posterior Estimation (NPE) is efficient for single observations but is inefficient for multiple observations as the simulator then needs to be called several times per setting of the simulator parameters to generate each training case. Neural Likelihood Estimation methods only require a single call to the simulator per training case but their performance is hampered by their reliance on the underlying inference method, which can introduce additional approximation errors and extra failure modes, e.g. struggling with multimodal distributions of the simulator parameters.

By contrast the described techniques can naturally handle sets of observations of arbitrary sizes without increasing the simulation cost, and can also suffer less from the limitations of previous techniques. In implementations the described techniques use a score generation neural network that models a posterior distribution over the simulator parameters in terms of a product of posterior distributions that are induced by, i.e. conditioned on, individual observations. In implementations the same score generation neural network is used to model the posterior distributions for all the parameters and all the observations, reducing the training cost. In implementations the score generation neural network models a gradient with respect to the simulator parameters, e.g. a gradient of a log probability density function (log-likelihood function) of the simulator parameters, that is used to gradually adjust the simulator parameters; such an approach facilitates modelling complex distributions.

Factorizing the posterior distribution is efficient but summing the scores for the observations might accumulate errors in some circumstances. An extension to the described technique factorizes the posterior distribution using small subsets of observations instead of individual observations, i.e. the posterior distribution is only partially factorized. This involves more simulator calls during training but can potentially provide better accuracy.

In general the described techniques are robust to design choices such as the size and architecture of the score generation neural network and, where applicable, to choices of hyperparameters of the system.

The ability of the system to handle varying numbers of observations at inference time, and to sample efficiently from multimodal posteriors, facilitates its use in scientific and engineering applications that require complex simulation systems. The described techniques are effective in such settings, and can significantly reduce the computation needed when applying simulation-based inference to real-world applications in science, medicine, and mechanical, electrical, chemical, and software engineering.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a block diagram of an example simulation-based inference neural network system and training engine.

FIG. 2 shows a particular example implementation of the simulation-based inference neural network system and training engine of FIG. 1.

FIG. 3 is a flow diagram of an example process for using a simulation-based inference neural network system to determine a set of simulator parameters.

FIG. 4 is a flow diagram of pre-processing that can be used for the process of FIG. 3.

FIG. 5 is a flow diagram of an example process for training a score generation neural network.

FIG. 6 illustrates the performance of some example implementations of the described system.

Like reference numbers and designations in the various drawings indicate like elements.

### DETAILED DESCRIPTION

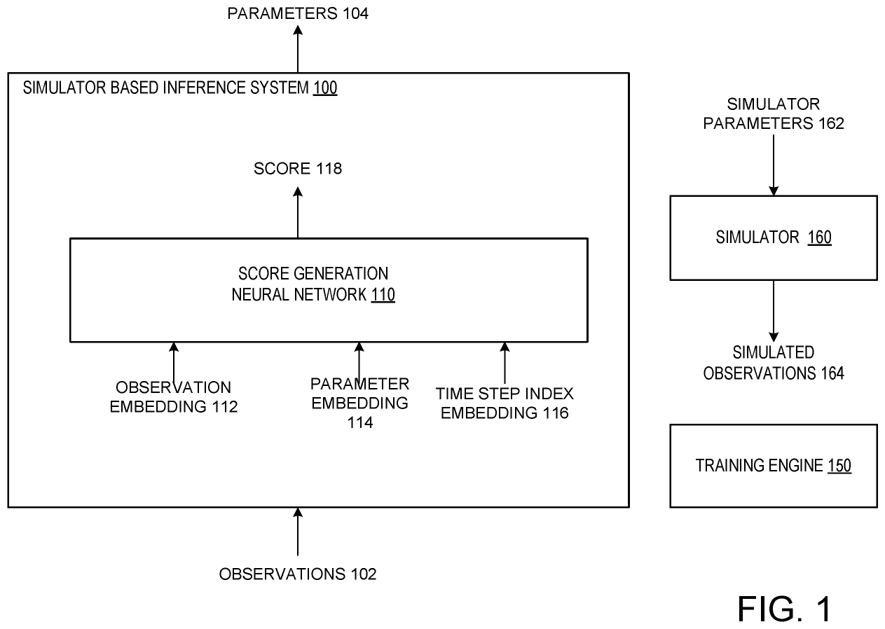

FIG. 1 shows an example simulation-based inference neural network system 100 and training engine 150. The simulation-based inference neural network system 100 is an example of a system implemented as one or more computer programs on one or more computers in one or more locations in which the systems, components, and techniques described below are implemented.

The system 100 is configured to receive a set of observations 102 and to process the observations to determine values of a set of simulator parameters 104. The observations may comprise observations of a physical system and the parameters may characterize the physical system. For example the observations 102 may be observations of physical reality, e.g. from one or more sensors, and the system 100 can be used as part of a measurement method that measures values of the set of parameters. Some particular examples are given later.

The system 100 comprises a score generation neural network 110 that is used to determine the set of simulator parameters 104. The score generation neural network 110 is configured to process an embedding 112 of one or more observations of the set of observations 102, an embedding 114 of a current value of one or more of, e.g. of each parameter of the set of simulator parameters 104, and an embedding of a current time step index 116, in accordance with learnable score neural network parameters, e.g. weights, to generate a score 118 for the one or more observations. The scores 118 are used to determine a parameter adjustment value for the current value of each simulator parameter.

In this specification, an “embedding” of an entity can refer to a representation of the entity as an ordered collection of numerical values, e.g., a vector or matrix of numerical values. An embedding of an entity can be generated, e.g., as the output of a neural network that processes data characterizing the entity, or as a result of some other encoding process.

The score generation neural network 110 can have any appropriate architecture, such as a feedforward neural network architecture, e.g. an MLP (Multi-Layer Perceptron) architecture, or a recurrent neural network architecture, or an attention-based neural network architecture. The neural network can include any appropriate types of neural network layers, e.g., one or more convolutional layers, or self-attention layers, or fully connected layers, or recurrent layers, and so forth, in any appropriate numbers, and connected in any appropriate configuration, e.g., as a linear sequence of layers or as a directed graph of layers.

The training engine 150 is used for training the score generation neural network 110, i.e. for updating the learnable score neural network parameters. The training uses training data items obtained from a simulator 160, e.g. a simulator of the physical system. In general the simulator 160 is only used during the training. An example process for training the score generation neural network 110 is described later.

The simulator 160 can be implemented as one or more computer programs on one or more computers in one or more locations, and can be treated as a black-box. The simulator 160 is used to generate synthetic, i.e. simulated observations 164, x, controlled by a set of simulator parameters 162, θ. In general the simulator 160 comprises a probabilistic model, i.e. it has a stochastic element, e.g. involving random sampling to generate a simulated observation.

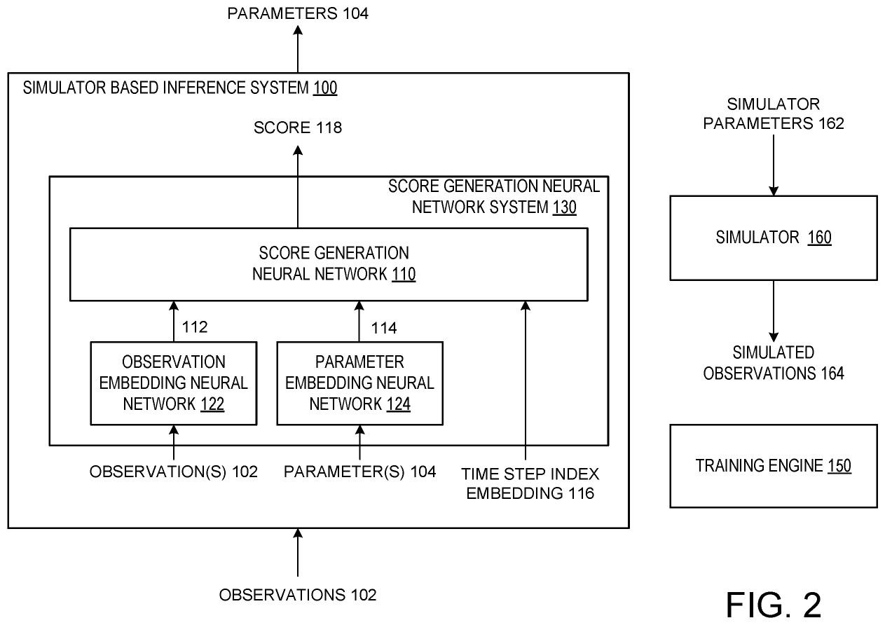

FIG. 2 shows a particular example implementation of the simulation-based inference neural network system 100 and training engine 150 of FIG. 1. Referring to FIG. 2, an embedding of each observation can be generated by processing each of the observations using an observation embedding neural network 122, e.g. a feedforward neural network such as an MLP.

In general an observation, x, of a set of n observations 102 {x₁, . . . , xₙ} may be a multidimensional vector in which each component represents a value associated with the observation. In some implementations the embedding 112 is an embedding of an individual, i.e. single, one of the set of observations 102, x_{emb}, and may be obtained as the output of the observation embedding neural network 122.

In some implementations the embedding 112 is an embedding of a group of observations of the set of observations 102, X_{emb}, and the score 118 may then depend on the group of observations. For example the embedding 112, X_{emb}, may be obtained by applying a permutation invariant transform to the group (e.g. from the observation embedding neural network 122), e.g. by summing or averaging the embeddings of the individual observations in the group, x_{emb}.

Where the score generation neural network 110 processes an embedding 112 of a group of observations, X_{emb}, if a number of observations in a group is variable the score generation neural network 110 may also be configured to process an embedding of a count of a number of embeddings in the group, n_{emb} where n_{emb} defines a number in the range 1 to m, where m is a maximum number of observations in the group. As an example n_{emb} may comprise a 1-hot encoding of the number of observations in the group.

An embedding of a current value of a simulator parameter can be obtained from a parameter embedding neural network 124, e.g., a feedforward neural network such as an MLP, in particular by processing the current value of the simulator parameter using the parameter embedding neural network 124. In general the set of simulator parameters may be defined by a multidimensional vector of parameters, θ, in which each component represents a value of one of the simulator parameters. The parameter embedding neural network 124 can be configured to process the vector of parameters, θ, to determine parameter embeddings 114, θ_{emb}, for the set of simulator parameters.

In implementations the embedding of the index of the current time step, t_{emb}, is determined by encoding the index as a d-dimensional vector. The index of the current time step, t_{emb}, is typically an integer. Any suitable encoding may be used, i.e. the system can generate the embedding of the index of the current time step as any appropriate function of the index; or the embedding may be learned. Merely as one example the value of each dimension i of the embedding may be sin(ωt) for even i and cos(ωt) for odd i, where ω=N^{-2i/d} where Nis an integer, typically a large number, e.g., 10000.

The score generation neural network 110 can generate the score 118 for the current value of the simulator parameter or for the set of simulator parameters, θ. In some implementations the score generation neural network 110 can generate the score 118 directly. In some implementations the score generation neural network 110 can generate the score 118 by generating one or more parameters of a distribution from which the score 118 sampled. In implementations the scores for the observations are summed to determine a respective parameter adjustment value for the current value of each simulator parameter.

In FIG. 2 a score generation neural network system 130 comprises the score generation neural network 110, the observation embedding neural network 122, and the parameter embedding neural network 124. The score generation neural network 110 may comprise, as an example, an MLP configured to process θ_{emb}, t_{emb}, and x_{emb} or X_{emb}, and optionally n_{emb}.

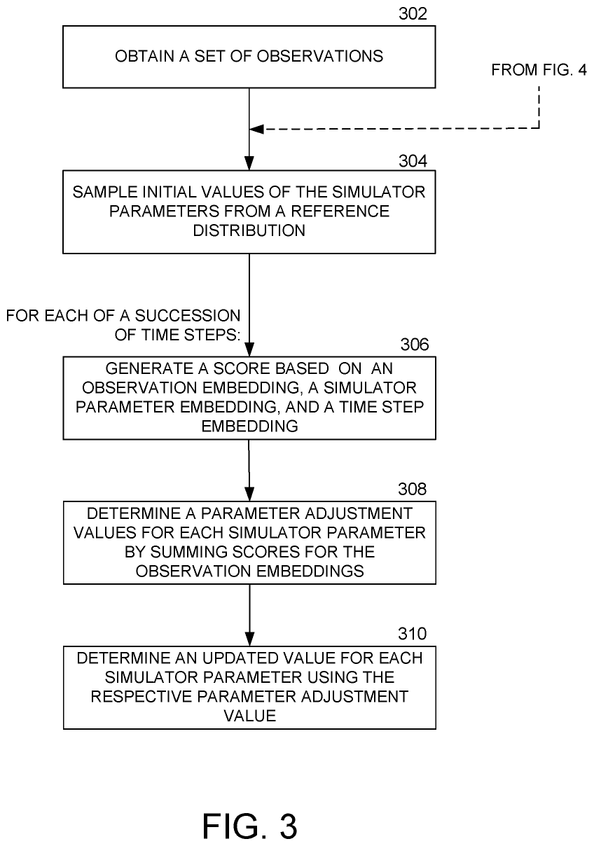

FIG. 3 is a flow diagram of an example process for using a simulation-based inference neural network system, e.g. the simulation-based inference neural network system 100 of FIG. 1 or FIG. 2, to determine a set of simulator parameters. The process of FIG. 3 can be used, for example, to make a measurement of a real-world physical system (simulated by the simulator 160 on which the system was trained), the measurement being defined by the set of one or more simulator parameters. In broad terms, the score generation neural network is used to determine scores, for individual observations or for groups of observations, that are combined and used to iteratively adjust values of the simulator parameters.

At step 302 the process receives a set of n observations, in implementations a set, c, of multiple observations 102, c={x₁, . . . , xₙ}.

At step 304 initial values for the set of simulator parameters, θ, are sampled from a reference distribution, p_{T}(θ). The subscript T refers to an initial time step, and with this notation the time steps are considered to count down, e.g. from T towards zero. The reference distribution can be, e.g., a Gaussian distribution, e.g.

$$𝒩 ( θ \vert 0 , \frac{1}{n} I )$$

where I is the identity matrix (with p_{T}(θ|xⱼ)≈ [symbol] (θ|0,I)), or some other distribution such a beta distribution or a uniform distribution. In some implementations the (simulator) model may be re-parameterized so that the prior becomes a standard Gaussian.

At each of a succession of time steps the process determines a respective parameter adjustment value for the current value of each simulator parameter based on the set of more observations {x₁, . . . , xₙ}.

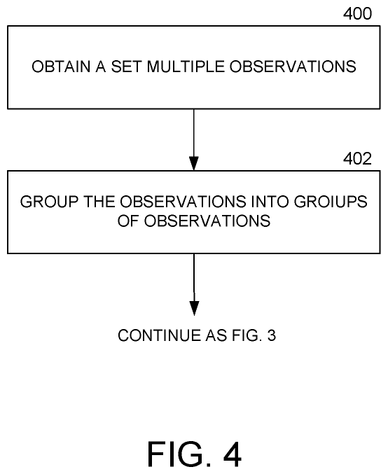

In one implementation of the process of FIG. 3 this involves processing the observations one at a time using the score generation neural network 110. When observations are pre-processed as described with reference to FIG. 4, the observations are processed in groups using the score generation neural network 110.

More particularly, at step 306 of the example process of FIG. 3 the score generation neural network 110 processes an embedding of the current values of the simulator parameters, θ, an embedding of one or more observations, and an embedding of an index of the current time step, t, to generate the score 118 for the embedding of the one or more observations. In some implementations the score generation neural network 110 processes an embedding of one of the observations, xⱼ, to generate the score 118 for the observation, s(θ, t, xⱼ). In some implementations the score generation neural network 110 processes an embedding of a group of observations, to generate the score 118 for the group of observations.

The scores for the observations are then summed, e.g. the score s(θ, t, xⱼ) for each observation is summed, in some implementations in a weighted sum, to determine the respective parameter adjustment value for the current value of each simulator parameter (step 308).

An updated value for each of the simulator parameters is then determined using the respective parameter adjustment value for the current value of each simulator parameter (step 310). In some implementations the simulator parameters are adjusted by their respective parameter adjustment values. In some implementations updated simulator parameter values are sampled from a distribution parameterized by the respective parameter adjustment values.

In some implementations determining the updated value for each of the simulator parameters includes adding noise to the updated value of each of the simulator parameters, e.g., by explicitly adding a noise value, or by sampling each of the simulator parameters from a distribution, or by corrupting an update value for each of the simulator parameters.

In some implementations the process reduces a level of the added noise over the succession of time steps, e.g., according to a noise (variance) reduction schedule. That is, the level of the added noise may gradually reduce as t decreases from a total number of time steps T towards 1. In general any noise reduction schedule may be applied.

Determining a respective parameter adjustment value for the current value of each simulator parameter may include adding a time-step dependent correction term to the summed scores for the observations. For example in some implementations a prior correction term may be added to correct for a prior distribution of the parameters, p(θ), e.g. a Gaussian distribution. For example the prior correction term may be determined as

$$\frac{( 1 - n ) ( T - t )}{T} {∇}_{θ} log p ( θ )$$

(where ∇_{θ} log p(θ) may be evaluated exactly).

In some implementations determining the updated value for each of the simulator parameters uses an approach based on Langevin dynamics. Determining the updated value for each of the simulator parameters may comprise adjusting each of the simulator parameters using the respective parameter adjustment value for the current value of the simulator parameter and for the set of observations, e.g., by adding the respective parameter adjustment value.

For example an approximate score for the set of observations, s(θ,t, c) can be obtained by summing the scores for the n individual observations, e.g. by determining s(θ,t, c) as

$${\sum }_{j = 1}^{n} s ( θ , t , {x}_{j} ) .$$

optionally a time-step dependent correction term such as a prior correction term as previously described, e.g.

$$\frac{( 1 - n ) ( T - t )}{T} {∇}_{θ} log p ( θ ) ,$$

may be added to the sum. The approximate score for the set of observations, s(θ,t, c) can be used to determine a respective parameter adjustment value for each of the simulator parameters, which is then used to determine an updated value for each of the simulator parameters, e.g. by adding the respective parameter adjustment value.

As one particular example determining the updated value for each of the simulator parameters uses a “Langevin step”, that involves updating the set of simulator parameters, θ, such that

$$θ ← θ + \frac{{δ}_{t}}{2} s ( θ , t , c ) + \sqrt{{δ}_{t}} {η}_{ts}$$

where ηₜₛ˜ [symbol] (θ|0, I), and δₜ is a step size that in general varies with time step t, in particular decreasing as t decreases from T towards 1. In implementations a plurality, L, of such Langevin steps is performed at each time step, to update the set of simulator parameters.

Continuing the particular example, determining the set of simulator parameters may involve sampling initial values for the set of simulator parameters as p˜p_{T}(0) at t=T, and then for each successive time step t=T−1, T−2, . . . , 1, performing L Langevin steps, s, each sampling noise according to ηₜₛ˜ [symbol] (θ|0, I) and updating the set of simulator parameters. The number of time steps and of Langevin steps will in general vary with the application and may be determined by routine experiment. Merely as an illustration, in one example T might be 400 and L might be 5. Merely as an illustration, in one example δₜ can be determined as δₜ=0.3(1−αₜ)/αₜ where α₁=γ₁ and αₜ=γₜ/γₜ₋₁ for t=2, . . . , T−1, and where 0≈γ_{T}<γ_{T-1}< . . . <γ₁<1 (where the values of γ define some step size schedule).

In some implementations determining the updated value for each of the simulator parameters uses an approach based on a reverse diffusion process. Determining the updated value for each of the simulator parameters may comprise sampling from a probability density distribution parameterized by the respective parameter adjustment value for the current value of the simulator parameter.

As one example, the probability density distribution can comprise a (multivariate) Gaussian distribution, and the respective parameter adjustment value (at a time step), for the current value of each simulator parameter and for the set of observations, can define a mean value of the Gaussian distribution (at the time step), μₜ. In implementations a variance, σₜ², for the Gaussian distribution can be determined dependent on the time step, in particular such that the variance (noise level) reduces for successive time steps. Then an updated value for each of the simulator parameters may be determined by sampling from the (multivariate) Gaussian distribution, e.g. as

$$θ ∼ 𝒩 ( θ \vert {μ}_{t} , {σ}_{t}^{2} I ) .$$

Summing the scores for the observations may comprise, for each observation, summing a linear combination of the current value of the simulator parameter and the score for the observation.

As a particular example implementation, for the case of a Gaussian distribution, and with the example schedule α₁=γ₁ and αₜ=γₜ/γₜ₋₁ for t=2, . . . , T−1 where 0≈γ_{T}<γ_{T-1}< . . . <γ₁<1, a linear combination, μⱼₜ, of the current value of the simulator parameter and the score for the observation xⱼ may be determined as

$${μ}_{jt} = \frac{1}{\sqrt{{α}_{t}}} ( θ + ( 1 - {α}_{t} ) s ( θ , t , {x}_{j} ) ) .$$

Determining the respective parameter adjustment value for the current value of the simulator parameter and for the set of observations may include determining a linear combination of the current value of the simulator parameter and the summed linear combination of the current value of the simulator parameter and the score for the observation. As previously described, this may also include adding a time-step dependent correction term to the determined linear combination.

Continuing the previous example, for the case of a Gaussian distribution and with the particular example schedule, the linear combination, μₜ, may be determined as a sum of μⱼₜ over n, more specifically by determining

$${\sum }_{j = 1}^{n} {μ}_{jt} - ( n - 1 ) \sqrt{{α}_{t}} θ .$$

Thus, for one particular example implementation, determining the set of simulator parameters may involve sampling initial values for the set of simulator parameters as p˜p_{T}(θ) and then for each successive time step t=T−1, T−2, . . . , 1, updating the set of simulator parameters by sampling from a distribution as

$$θ ∼ 𝒩 ( θ \vert {μ}_{t} , {σ}_{t}^{2} I ) , \\ where {μ}_{t} = \frac{{\sum }_{j = 1}^{n} {μ}_{jt} - ( n - 1 ) \sqrt{{α}_{t}} θ}{n - {α}_{t} ( n - 1 )} and {σ}_{t}^{2} = \frac{1 - {α}_{t}}{n - {α}_{t} ( n - 1 )} ,$$

and where optionally a prior correction term

$$\frac{{σ}_{t}^{2} ( 1 - n ) ( T - t )}{T} {∇}_{θ} log p ( θ ) ,$$

Determining updated values the simulator parameters by summing the scores for individual observations as described above can accumulate errors. One way to address this would be to train a single score generation neural network on different numbers of observations, but this would be inefficient in a system intended to cope with varying numbers of individual observations as the neural network would need to be trained on a range of different numbers of observations, requiring a large number of simulator calls. This can be addressed by grouping the observations into small subsets of observations that are processed together.

FIG. 4 is a flow diagram of pre-processing that may be used for the process of FIG. 3. In FIG. 4, at step 400 the process receives a set, c, of multiple observations 102, c={x₁, . . . , xₙ}.

The process groups a plurality of the observations into a group of observations (step 402). More particularly subsets of the observations are grouped into groups of observations, e.g. groups with varying numbers of sets of observations. The groups can have varying numbers of sets of observations where a number of observations in the set of observations is not constrained to be an integer multiple of the group (subset) size. In implementations the groups are disjoint groups with disjoint subsets of observations.

As an example, the set, c, of multiple observations 102, {x₁, . . . , xₙ} may be partitioned into k=┌n/m┐ disjoint subsets of size at most m where m≥1, more particularly where m>1 and, in implementations, where m<n, i.e. where the number of observations in a group of observations is less than a number of observations in the set of observations. ┌⋅┐ denotes the ceiling function, i.e. the least integer equal to or greater than n/m. The disjoint subsets may be denoted X₁, . . . , Xₖ. In general each subset Xⱼ can have a size, i.e. number of observations, that varies between 1 and m.

The process can then continue as previously described with reference to FIG. 3, starting at step 304, but with Xⱼ replacing xⱼ and with k replacing n and n_{emb} being an embedding of k, i.e. subsets of the observations are processed rather than individual observations. For example the process uses the score generation neural network 110 to collectively process the embeddings of a group of observations, i.e. to process an embedding X_{emb} rather than the embedding of an individual observation, x_{emb}, to generate the score 118.

The score generation neural network 110 can collectively process the embeddings of a group or subset of observations, e.g. by averaging the individual observation embeddings to obtain a final embedding of the group, X_{emb}, that is processed by the score generation neural network 110 to generate the score 118.

For example, for each of the observations processing, using the trained score generation neural network, an embedding of the current value of the simulator parameter(s), an embedding of the observation, and an embedding of an index of the current time step, to generate the score for the observation, may comprise processing, using the trained score generation neural network, the embedding of the current value of the simulator parameter(s), an embedding a group of the observations, X_{emb}, and the embedding of an index of the current time step, to generate the score for the observation.

Optionally the score generation neural network 110 processes both the embedding of the group, X_{emb}, and the embedding of the count of the number of embeddings in the group, n_{emb} (=k_{emb}), as well as the embeddings of the simulator parameter(s) and of index of the current time step.

The maximum size of a group, i.e. the value of m, controls a trade-off between computing resources in particular sample efficiency, i.e. how many observations, i.e. simulator calls, are needed to train the score generation neural network 110, and the accuracy of parameter estimation, i.e. error accumulation when summing the scores for observations. In some implementations m can be relatively small, e.g. 1<m≤10.

In general the score generation neural network 110 is trained to approximate the score of a noisy or “diffused” version of an individual observation, x, or of a group of observations, X.

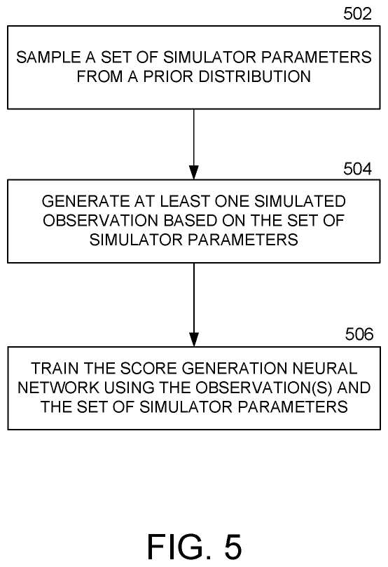

FIG. 5 is a flow diagram of an example process for training a score generation neural network to generate a score. The process of FIG. 5 can be performed by a system of one or more computers located in one or more locations, e.g. by the training engine 150 of FIG. 1 or FIG. 2. For convenience the process will be described with reference to the score generation neural network 110 of FIG. 1 and FIG. 2.

The process involves obtaining a set of training examples. A training example can be obtained by sampling values for (each of) a set of simulator parameters, θⁱ, from a prior distribution over the simulator parameters, p(θ) (step 502).

Then at least one simulated observation, xⁱ, is generated using the simulator (step 504), by operating the simulator in accordance with the sampled values for the set of simulator parameters, θⁱ. The process can also involve determining, e.g., sampling, a value for a time step, i.e. an index of a time step.

The score generation neural network 110 is trained (step 506), using the simulated observation(s) and the sampled set of simulator parameters in each training example (and, in some implementations, also using the index of a time step). The observation embedding neural network 122 and the parameter embedding neural network can be trained at the same time as the score generation neural network 110.

In general training the score generation neural network 110 comprises backpropagating gradients of an objective function based on the score 118 generated by the score generation neural network 110 for the simulated observation(s), to update the score neural network parameters. The score neural network parameters can be updated using any appropriate gradient descent optimization algorithm, e.g. Adam or another optimization algorithm.

In some implementations the score generation neural network is trained to approximate the scores of the distributions induced by individual observations. At inference time the scores from the score generation neural network 110 can be aggregated as previously described to sample the target posterior score distribution. Such an approach can aggregate an arbitrary number of observations at inference time while training on samples (θ, x) that each require just a single simulator call, where (0ⁱ, xⁱ) denotes an ith training example.

In some implementations multiple simulated observations can be sampled for a set of simulator parameters θⁱ, e.g.

$${x}_{1}^{i} , … , {x}_{{n}^{i}}^{i}$$

Where 1≤nⁱ≤m and where nⁱ for an ith training example is sampled from a uniform distribution. Thus subsets of observations can be grouped, e.g., into groups with varying numbers of sets of observations, e.g., disjoint groups with disjoint sets of observations. The training process can involve partitioning the set of training examples into a plurality of groups of training examples, each group including a set (subset) of one or more of the observations (for the same set of simulator parameters). In implementations the groups include different numbers of training examples. An ith such group of training examples may be denoted

$$( {n}^{i} , {θ}^{i} , {x}_{1}^{i} , … , {x}_{{n}^{i}}^{i} )$$

and, as such, may be considered as a single training example comprising multiple observations.

The groups of observations can be used to train the score generation neural network 110. That is, the score generation neural network 110 can be used to collectively process the sets (subsets) of observations in each group to generate a score for training the score generation neural network. At inference time observations can be grouped and processed collectively by the score generation neural network 110, as previously described.

In some implementations the score generation neural network 110 is configured to process embeddings of the simulator parameters, an embedding of each of the observations in the group of training examples (combined, e.g. averaged), a count of a number of sets of observations in the group, more particularly an embedding, e.g. 1-hot encoding of the count, and an embedding of the index of the current time step, to generate the score 118 for the observation.

The training can involve applying a permutation invariant transform to the sets of observations in each group, e.g., by summing or averaging them. Each group of training examples can then be processed using the score generation neural network 110, and with the count of a number of the observations equal to the number of training examples in the subset. The score generation neural network 110 can then be trained using an objective function based on the score for the group of observations, e.g. on a score obtained by processing

$$( {n}^{i} , {θ}^{i} , {x}_{1}^{i} , … , {x}_{{n}^{i}}^{i} ) .$$

In more detail, training the score generation neural network may comprise, for each of the simulator parameters, and for each of a sequence of one or more training time steps, using the score generation neural network 110 to process an embedding of the sampled value of the simulator parameter, an embedding of the simulated observation, and an embedding of an index of the time step, in accordance with current values of score neural network parameters, to generate a score 118 for the observation. In general the score generation neural network 110 processes the simulator parameters together, as a set of parameters, e.

As described below, although in inference the indices of the current time steps processed by the score generation neural network 110 may be considered to define a sequence t=T−1, T−2, . . . , 1, when the generation neural network 110 is trained it is not necessary to train using a sequence of time steps that either increases or decreases. That is, during training the generation neural network 110 can be presented with an embedding of an index of any time step t.

The method may determine a gradient (with respect to the score neural network parameters) of an objective function dependent on a difference between the score for the observation and a score determined from the sampled values for the set of simulator parameters. This may, but need not be summed over the one or more training time steps. The current values of the score neural network parameters may then be updated using the gradient, e.g., by backpropagation.

In implementations the method includes adding noise to each of the sampled values for the set of simulator parameters at one or more training time steps, e.g., at each training time step of the sequence of training time steps. As a particular example, if training time steps range between t=1 and t=T−1 or t=T the added noise may be such that there is less noise when t is closer to 1.

As one example, the objective function, e.g. a loss lₜ, can depend on

$${‖ s ( θ , t , c ) - {∇}_{θ} log log {p}_{t} ( θ \vert {θ}^{′} ) ‖}_{2}^{2}$$

where ∥⋅∥₂ denotes the 2-norm, where pₜ(θ|θ′)= [symbol] (θ|\sqrt{γₜ}θ′, (1−γₜ)I) is a noise distribution that perturbs θ′ to θ, and where, as above, 0≈γ_{T}<γ_{T-1}< . . . <γ₁<1 (equivalently αₜ as defined above can be used in place of γₜ). This is one example of a choice of noise distribution (there are others that can be used) for which ∇_{θ} log pₜ(θ|θ′) can be evaluated in closed form as

$$- \frac{( θ - {θ}^{′} )}{{σ}^{2}}$$

where σ²=(1−γₜ). In general ∇_{θ} log pₜ(θ|θ′) can be evaluated for an arbitrary t. In some implementations, but not essentially, the loss can be evaluated as a sum over t, optionally but not essentially a weighted sum, e.g. as

$${\sum }_{t = 1}^{T - 1} {l}_{t}$$

or as

$${\sum }_{t = 1}^{T - 1} λ ( t ) {l}_{t}$$

where λ(t) a non-negative weight.

In general the score 118 for one or more observations generated by the score generation neural network 110 is defined by a gradient of a log probability density (log likelihood) of the simulator parameters with respect to the simulator parameters (∇_{θ} log pₜ(θ)), and thus the score can define a “direction” in which to move to increase the likelihood of set of simulator parameters.

In general the score generation neural network 110 described herein can be trained using techniques for training so-called diffusion models, e.g. as described in Song et al. arXiv: 1907.05600, Ho et al. arXiv: 2006.11239, or Luo, arXiv: 2208.11970.

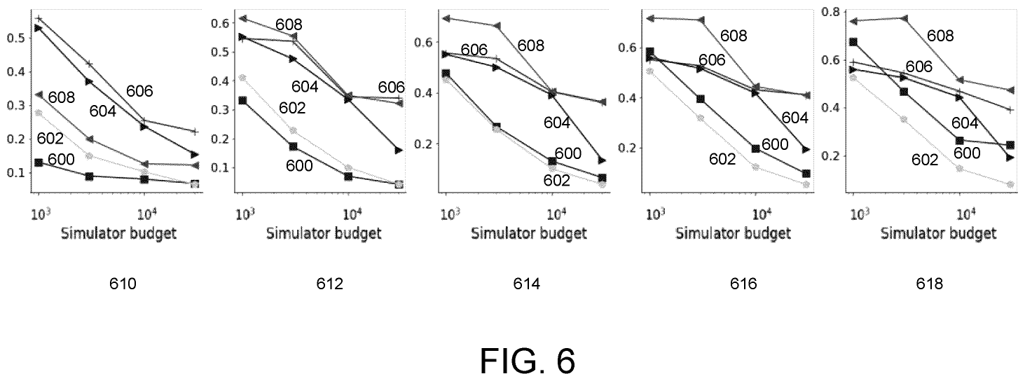

FIG. 6 illustrates the performance of some example implementations of the described simulation-based inference neural network system 100. In the illustration of FIG. 6 the task is to determine, from noisy observations, parameters that represent a contact rate and a recovery rate characterizing the evolution of a disease. The observations comprise observations of the number of individuals in a susceptible state(S), in an infected state (I), and in a recovered state (R) at different times. The simulator models S, I and R based on the contact rate and the recovery rate.

In FIG. 6 the y-axis represents a measure of error in the determined parameters (lower is better). Plots 610, 612, 614, 616, and 618 are for, respectively, n=1,8,14,22,30 conditioning observations at inference time. Curve 602 shows the performance of a system as described herein that groups the observations into groups of observations to determine the score, where m<n. Curve 600 shows the performance of a system as described herein that determines the score by summing the scores for the individual observations. Curve 604 shows the performance of a system that groups the observations into groups of observations to determine the score, where m=n. Curve 606 shows the performance of a system that uses Neural Posterior Estimation (NPE) as described in Dinh et al., arXiv: 1605.08803. Curve 608 shows the performance of a system that uses Neural Ratio Estimation (NRE) as described in Hermans et al., arXiv: 1903.04057. The x-axis shows the simulator budget used to train the system.

A few example applications of the simulation-based inference neural network system 100 will now be described.

In some implementations the simulator 160 is configured to simulate the response of a measurement system. Then the set of simulator parameters may characterize one or more real-world entities or signals relating to one or more real-world entities sensed by the measurement system. The observations may comprise sensed signals, provided by the measurement system, relating to the real-world entities or to the signals. These may be derived from any type of sensor including, but not limited to, an optical, electrical (including electromagnetic radiation), magnetic, radiation, chemical/biochemical, mechanical (including movement, force, and acoustic/vibration), flow, environmental (including temperature and pressure). Merely as one example the observations may be derived from an image sensor (as used herein “image” includes video and LIDAR).

A method of determining a set of simulator parameters as described herein may then include capturing the set of observations using the measurement system (which may include or be coupled to one or more such sensors), and characterizing one of more of the real-world entities or signals relating to real-world entities using the determined set of simulator parameters. Optionally one or more of the determined set of simulator parameters may then be used to control the subject of the measurement system, or diagnose a fault in the subject of the measurement system. In general the subject of the measurement system may be a physical object, or an electrical, optical, or mechanical system including, e.g., a computing system.

As an example, the real-world entity may comprise an engine or motor, e.g., an internal combustion engine, gas turbine, or electric motor; or a fluid flow system or fluidized bed; or a mixing system that mixes components in a container; or a manufacturing plant; or an electricity generating station. The observations may comprise any observable relating to the operation or performance; and the determined parameters may characterize the operation or performance e.g., for fault-finding or diagnosis, or for optimizing the performance of the entity, e.g., the yield (quantity or quality) of a manufacturing facility.

Where the real-world entity comprises a manufacturing facility (large scale or lab scale) or electricity generating station the determined parameters may be used for controlling the performance of a task, e.g., to manufacture a product or to control, e.g., minimize, use of a resource such as electrical power, or water, or a consumable. Controlling the performance may comprise controlling the use of a machine or a manufacturing unit for processing a solid or liquid material to manufacture the product, or an intermediate or component thereof, e.g., controlling movement of an intermediate version or component of the product within the manufacturing environment, or adjusting the physical or chemical conditions of a manufacturing unit. Controlling an electricity generating station may comprise controlling power generated by the facility, e.g., controlling electrical voltage, current, frequency or phase, or controlling delivery of electrical power to a power distribution grid, e.g., controlling an electrical or mechanical configuration of one or more power generating elements.

In some implementations the simulator 160 is configured to simulate the response of a scientific or medical instrument. The set of simulator parameters may characterize real-world entities or signals relating to real-world entities sensed by the scientific or medical instrument. The observations may be observations relating to (of) the real-world entities or relating to (of) the signals relating to the real-world entities. The observations may be obtained from one or more sensors, e.g., as previously described, associated with the scientific or medical instrument. A method of determining a set of simulator parameters as described herein may then include capturing the set of observations using the scientific or medical instrument (which may include or be coupled to one or more such sensors), and characterizing one of more of the real-world entities or signals relating to real-world entities using the determined set of simulator parameters.

As one example, the scientific instrument may comprise a microscope. The simulation of the microscope may comprise a simulation of a subject of the microscope, e.g., single- or multi-emitters in single-molecule localization microscopy. The simulation may, e.g., include a simulation of a point spread function of the microscope; the observations may comprise images captured by the microscope and the determined parameters may characterize the subject, e.g., localize the emitters in one, two, or three dimensions.

As another example, the scientific instrument may comprise a telescope or gravitational wave observatory. The observations may comprise images captured by the telescope or strain data from the gravitational wave observatory. The determined parameters may characterize the subject, e.g., the type, number, and disposition of stars in a galaxy viewed by the telescope, or the locations, masses and spins of merging black holes.

As another example, the scientific instrument may comprise a particle physics detector, the observations may comprise observables of the detector, e.g., collisions, radiation patterns, decays, and various sensor readouts, and the determined parameters may define or characterize (elementary) particles and their interactions.

As another example, the scientific instrument may comprise a DNA or RNA sequencing machine, the observations may comprise observations of DNA or RNA sequences from one or more physical (biological) sources such as cells, e.g., of SNPs (Single Nucleotide Polymorphisms); and the determined parameters may relate to properties or characteristics of the observed sequences, or of a population of the sequences, e.g., recombination hotspots.

As another example the medical instrument may comprise a medical “body scanner” such as an MRI (magnetic resonance imaging) or CT (computed tomography) or PET (positron emission tomography) machine, e.g. for scanning a human or animal body, the observations may comprise magnetic resonance signals, or x-ray detection signals, or radiation signals from the machine, and the determined parameters may comprise parameters characterizing the imaged body or a part of the body or the function of a body part.

As another example the medical instrument may comprise an EEG (Electroencephalography), MEG (Magnetoencephalography), EMG (Electromyography), or ECG (Electrocardiogramhy) machine, the observations may comprise electrical or magnetic signals from the machine, i.e. from a human or animal body and captured using the machine, and the determined parameters may comprise parameters characterizing the subject of the machine, e.g., brain/neuronal circuit, muscle, or heart function.

In some implementations the simulator 160 is configured to simulate the operation or performance of a physical object, or of an electrical, optical, mechanical, chemical or biological system. The set of simulator parameters may characterize the operation or performance of the physical object, or electrical, optical, mechanical, chemical or biological system. The observations may comprise observations derived from sensed signals relating to the operation or performance of the physical object, or electrical, optical, mechanical, chemical or biological system. A method of determining a set of simulator parameters as described herein may then include obtaining the sensed signals from one or more sensors, obtaining the set of observations from the sensed signals, and characterizing the operation or performance of the physical object, or electrical, optical, mechanical, chemical or biological system using the determined set of simulator parameters.

For example, the simulator 160 may comprise a biological model such as a model of a biological system, e.g., a model based on systems biology or a model of ligand-receptor interactions. The observations may comprise any observables of a particular biological system and the determined parameters may comprise parameters of the biological model for the particular biological system. Such implementations may be used, e.g., to screen potential ligands for biological activity to identify a drug or, where the observations are of a patient, to determine one or more parameters that diagnose a medical condition in the patient.

As another example, the simulator 160 may comprise an epidemiological model, the observations may comprise infection counts, and the determined parameters may comprise the contact rate and/or the mean recovery rate.

In some implementations the simulator 160 is configured to simulate the operation or performance of a computer system or network. The set of simulator parameters may characterize the operation or performance of the computer system or network. The observations may comprise observations derived from signals or data relating to the operation or performance of the computer system or network. A method of determining a set of simulator parameters as described herein may then include obtaining a set of observations comprising signals or data relating to the operation or performance of the computer system or network, and characterizing the operation or performance of the computer system or network using the determined set of simulator parameters. The determined parameters may be used to configure the computer system or network, e.g., for more efficient operation, such as faster processing or a reduced memory requirement, or to correct a defect in the operation or performance.

For example, the simulator 160 may comprise a model describing the processing, e.g., by a (single) server, of a queue with continuously arriving tasks or jobs. The observations may comprise, e.g., observations of the times of departures of successive tasks or jobs or the time intervals between the departures of successive tasks or jobs. The determined parameters may comprise, e.g., parameters defining the time the server takes to process each task or job, e.g., the start and end of a range of times; and/or the arrival times, or time intervals between the arrivals, of two successive tasks or jobs. Optionally the determined parameters may then be used to control the server queue, e.g. to manage the tasks or jobs.

As another example the simulator 160 may comprise a model representing the operation of the computer system or network, the observations may comprise any observations characterizing this operation, and the determined parameters may characterize a likelihood or abnormal operation, e.g., because of the presence of a virus or other security breach. Optionally the determined parameters may then be used to control the operation of the computer system or network, e.g. to inhibit the running of code with a virus or other security breach.

Some implementations of the simulation-based inference neural network system 100 may be used for designing a physical object, or an electrical, optical, or mechanical system. This may comprising iteratively, for one or more iterations, making a prototype of the physical object, or an electrical, optical, mechanical, chemical or biological system; configuring the simulator 160 to simulate the operation or performance of the prototype; obtaining observations relating to the operation or performance of the prototype; and using a process as previously described to determine a set of simulator parameters that characterizes the operation or performance of the prototype. The prototype may then be modified or updated based on the characterization of the operation or performance, to improve the design. The process may include making the physical object, or the electrical, optical, mechanical, chemical or biological system according to a final design iteration.

As some examples, such an approach may be used for designing a medical device such as a stent or inhaler, where complex simulation may be involved; or for designing an integrated circuit, e.g., a microprocessor, or an RFIC (radio frequency integrated circuit); or for designing an RF antenna; or for designing an optical system; or for designing a fusion-based electrical power generator; or for designing an engine such as electric motor or gas turbine.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions. Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub programs, or portions of code. A computer program can be deployed to be executed on one computer or on multiple computers that are located at one site or distributed across multiple sites and interconnected by a data communication network.

In this specification, the term “database” is used broadly to refer to any collection of data: the data does not need to be structured in any particular way, or structured at all, and it can be stored on storage devices in one or more locations. Thus, for example, the index database can include multiple collections of data, each of which may be organized and accessed differently.

Similarly, in this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework.

Embodiments of the subject matter described in this specification can be implemented in a computing system that includes a back end component, e.g., as a data server, or that includes a middleware component, e.g., an application server, or that includes a front end component, e.g., a client computer having a graphical user interface, a web browser, or an app through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are correspond toed in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes correspond toed in the accompanying figures do not necessarily require the particular order shown, or sequential order, to achieve desirable results. In some cases, multitasking and parallel processing may be advantageous.

What is claimed is:

1. A computer-implemented method of determining a set of simulator parameters for a simulator, wherein the simulator is configured to generate a simulated observation in accordance with the set of simulator parameters, the method comprising:
receiving a set of observations;
sampling initial values for the set of simulator parameters from a reference distribution; and
at each of a succession of time steps updating current values for the set of simulator parameters by:
determining, for each of the simulator parameters, a respective parameter adjustment value for the current value of the simulator parameter and for the set of observations; and
determining an updated value for each of the simulator parameters, using the respective parameter adjustment value for the current value of the simulator parameter;
wherein, for each of the simulator parameters, determining the respective parameter adjustment value for the current value of the simulator parameter and for the set of observations comprises:
for each of the observations: processing, using a trained score generation neural network, i) an embedding of the current value of the simulator parameter, ii) an embedding of the observation, and iii) an embedding of an index of the current time step, to generate a score for the observation; and
summing the scores for the observations to determine the respective parameter adjustment value for the current value of the simulator parameter.

2. The method of claim 1, further comprising:
grouping a plurality of subsets of observations into groups of observations; and
using the score generation neural network to collectively process the embeddings of a group of observations to generate the score.

3. The method of claim 1, wherein determining the updated value for each of the simulator parameters includes adding noise to the updated value of each of the simulator parameters.

4. The method of claim 3, comprising reducing a level of the added noise over the succession of time steps.

5. The method of claim 1, wherein determining the updated value for each of the simulator parameters using the respective parameter adjustment value for the current value of the simulator parameter and for the set of observations, comprises adjusting each of the simulator parameters using the respective parameter adjustment value for the current value of the simulator parameter and for the set of observations.

6. The method of claim 1, wherein determining the respective parameter adjustment value for the current value of the simulator parameter further comprises adding a time-step dependent correction term to the summed scores for the observations.

7. The method of claim 1, wherein determining the updated value for each of the simulator parameters, using the respective parameter adjustment value for the current value of the simulator parameter and for the set of observations, comprises sampling from a probability density distribution parameterized by the respective parameter adjustment value for the current value of the simulator parameter.

8. The method of claim 7, wherein summing the scores for the observations comprises, for each observation, summing a linear combination of the current value of the simulator parameter and the score for the observation.

9. The method of claim 8, wherein determining the respective parameter adjustment value for the current value of the simulator parameter and for the set of observations further comprises determining a linear combination of i) the current value of the simulator parameter and ii) the summed linear combination of the current value of the simulator parameter and the score for the observation.

10. The method of claim 9, wherein determining the respective parameter adjustment value for the current value of the simulator parameter and for the set of observations further comprises adding a time-step dependent correction term to the determined linear combination.

11. The method of claim 7, wherein the probability density distribution comprises a Gaussian distribution, and wherein the respective parameter adjustment value for the current value of the simulator parameter and for the set of observations defines a mean value of the Gaussian distribution.

12. The method of claim 11, further comprising determining a variance for the Gaussian distribution dependent on the time step such that the variance reduces for successive time steps.

13. The method of claim 1, comprising processing the current value of the simulator parameter using a parameter embedding neural network to generate the embedding of the current value of the simulator parameter.

14. The method of claim 1, comprising processing each of the observations using an observation embedding neural network to generate the embedding of each observation.

15. The method of claim 1, comprising determining the embedding of the index of the current time step by encoding the index as a d-dimensional vector.

16. (canceled)

17. (canceled)

18. (canceled)

19. (canceled)

20. (canceled)

21. The method of claim 1, wherein the simulator is configured to simulate the response of a measurement system; wherein the set of simulator parameters characterize one or more real-world entities or signals relating to one or more real-world entities sensed by the measurement system; and wherein the observations comprise sensed signals, provided by the measurement system, relating to the real-world entities or to the signals; the method further comprising:
capturing the set of observations using the measurement system; and
characterizing one of more of the real-world entities or signals relating to real-world entities using the determined set of simulator parameters.

22. The method of claim 1, wherein the simulator is configured to simulate the response of a scientific or medical instrument; wherein the set of simulator parameters characterize one or more real-world entities or signals relating to one or more real-world entities sensed by the scientific or medical instrument; and wherein the observations are observations relating to the real-world entities or to the signals relating to the real-world entities, by the scientific or medical instrument; the method further comprising:
capturing the set of observations using the scientific or medical instrument; and
characterizing one of more of the real-world entities or signals relating to real-world entities using the determined set of simulator parameters.

23. The method of claim 1, wherein the simulator is configured to simulate the operation or performance of a physical object, or of an electrical, optical, mechanical, chemical or biological system; wherein the set of simulator parameters characterize the operation or performance of the physical object, or electrical, optical, mechanical, chemical or biological system; and wherein the observations are observations derived from sensed signals relating to the operation or performance of the physical object, or electrical, optical, mechanical, chemical or biological system; the method further comprising:
obtaining the sensed signals from one or more sensors;
obtaining the set of observations from the sensed signals; and
characterizing the operation or performance of the physical object, or electrical, optical, mechanical, chemical or biological system using the determined set of simulator parameters.

24. (canceled)

25. (canceled)

26. One or more computer storage media storing instructions that when executed by one or more computers cause the one or more computers to perform operations for determining a set of simulator parameters for a simulator, wherein the simulator is configured to generate a simulated observation in accordance with the set of simulator parameters, the operations comprising:
receiving a set of observations;
sampling initial values for the set of simulator parameters from a reference distribution; and
at each of a succession of time steps updating current values for the set of simulator parameters by:
determining, for each of the simulator parameters, a respective parameter adjustment value for the current value of the simulator parameter and for the set of observations; and
determining an updated value for each of the simulator parameters, using the respective parameter adjustment value for the current value of the simulator parameter;
wherein, for each of the simulator parameters, determining the respective parameter adjustment value for the current value of the simulator parameter and for the set of observations comprises:
for each of the observations: processing, using a trained score generation neural network, i) an embedding of the current value of the simulator parameter, ii) an embedding of the observation, and iii) an embedding of an index of the current time step, to generate a score for the observation; and
summing the scores for the observations to determine the respective parameter adjustment value for the current value of the simulator parameter.

27. A system comprising:
one or more computers; and
one or more storage devices communicatively coupled to the one or more computers, wherein the one or more storage devices store instructions that, when executed by the one or more computers, cause the one or more computers to perform operations for determining a set of simulator parameters for a simulator, wherein the simulator is configured to generate a simulated observation in accordance with the set of simulator parameters, the operations comprising:
receiving a set of observations;
sampling initial values for the set of simulator parameters from a reference distribution; and
at each of a succession of time steps updating current values for the set of simulator parameters by:
determining, for each of the simulator parameters, a respective parameter adjustment value for the current value of the simulator parameter and for the set of observations; and
determining an updated value for each of the simulator parameters, using the respective parameter adjustment value for the current value of the simulator parameter;
wherein, for each of the simulator parameters, determining the respective parameter adjustment value for the current value of the simulator parameter and for the set of observations comprises:
for each of the observations: processing, using a trained score generation neural network, i) an embedding of the current value of the simulator parameter, ii) an embedding of the observation, and iii) an embedding of an index of the current time step, to generate a score for the observation; and
summing the scores for the observations to determine the respective parameter adjustment value for the current value of the simulator parameter.
